(19) United States
(12) Patent Application Publication
(10) Pub. No.: US 2022/0060188 A1
(43) Pub. Date: Feb. 24, 2022

(54) Decryption

(71) Applicant: Rashad Zaguia, Ksar Helal (TN)

(72) Inventor: Rashad Zaguia, Ksar Helal (TN)

(21) Appl. No.: 17/407,180

(22) Filed: Aug. 19, 2021

Related U.S. Application Data
(63) Continuation-in-part of application No. 16/024,909, filed on Jul. 1, 2018.

(51) Int. Cl. H03K 19/173; H03K 19/17736; H03K 19/20

(52) U.S. Cl. CPC H03K 19/1733; H03K 19/20; H03K 19/17744

(57) ABSTRACT

Using switches at the inputs surface of the circuit and any conductor we can make any combinatorial logic gates circuit where the inputs and outputs are distinct. Switches do disconnect some 2 pins and connect some 2 pins at a state and do the reverse at the other state. It is possible to have memory by having the outputs back to the inputs if the switches are made with transistor like switches.

### TECHNICAL FIELD

The convertibility of work to money frees inventions from their original purpose and makes them become tools, it also funds inventors for their inventions through licensing or adding patents to capitals.

Fields of the invention include digital circuits, foundations of computer architecture, simplification of a universal logic gate, first order logic, materialization of software/algorithms and networking.

### BACKGROUND ART

Relays, vacuum tubes and semi-conductor transistors where used as circuit switches to make universal logic gates.

The logic gate NOR is known to be universal as much as the logic gate NAND.

One of those universal gates when used many time in a structure can make a processor or materialize an algorithm.

There are less standard ways to make a universal logic gate like carbon transistors, molecular, thermal, DNA, chemical, bio-molecular or ring resonator based universal logic gates.

But none is with the simplicity of having all the switches on the input interface without using any other materials characteristics other than their ability to connect pins.

### SUMMARY OF INVENTION

Using switches at the inputs surface of the circuit and any conductor we can make any combinatorial logic gates circuit.

It allows a very high speed at a very low cost all that possibly without the use of semi-conductors.

By combinatorial logic gates circuit, we mean a circuit with distinct inputs and outputs (no outputs are forwarded back to the inputs).

By switches we mean (mechanical like) switches that disconnect some 2 pins and connect some 2 pins at a state and do the reverse at the other state.

Signals could be of light (eyes reach), of gas (ears reach), of solid (nose reach) or of liquid (tongue reach).

A transistor like switch can be by having a signal use to cut or allow the flow of a similar signal.

A special switch can be by having 2 transistors if the signal is electric.

It is possible to have memory by having the outputs back to the inputs if the switches are made with transistor like switches.

### Technical Problem

If a gate in the set {‘XNOR’, ‘XOR’ } is verification and a gate in the set {‘NAND’, ‘NOR’ } is implementation can we make implementation with verification only? Can we make implementation with wires only?

### Solution to Problem

Evolution of the Solution

Step 1:

See FIG. 47.

Made with 9 XORs each 3 of them are making a tripleXor.

A tripleXor is obtained by having every output of every one of the involved three xors connected to 2 inputs keeping them away from direct wire connection.

A tripleXor pins are pins capable of input and of output.

A changeable value is a value separated with a resistance from the input output pin.

If a pin fires back a different value than the input value the resistance would separate the 2 values.

All tripleXors have one pin connected to pin0 and another connected to 1.

TripleXors third pins are connected to changeable values 0 pin1 and pin2 as displayed in FIG. 47.

Pin0 would be equal to pin1 NAND pin2.

The use of resistances is for practical reasons.

FIG. 47 demonstrates the possible use of verification for implementation.

Step 2:

How to obtain a not with wires only?

Let's have two wires and flip them.

Entering two different signals on a side of the two wires would have them reordered on the other side.

An order of the two values represents 0 and the other order represents 1.

See FIG. 5.

What can we obtain when we use wires instead of triple XORs?

Each of the wires has 2 ends, one of the ends of every one of the 3 wires is connected to the out pin. The other end of one of the wires is connected to a constant. The other 2 ends of the other 2 wires are inputs.

A majority vote that would approximate an ‘AND’ gate if the constant is 0 otherwise it would approximate an ‘OR’ gate.

See FIGS. 48 and 49 for a display of all the cases.

FIGS. 54 to 61 represent an electric version of the two functions.

FIGS. 1 to 4 demonstrate a way to construct a universal gate using an ‘OR’ gate with an ‘AND’ gate.

FIGS. 50 to 53 demonstrate replacing all with wires only in an approximation.

Step 3:

How to remove the approximation? Let's have a wire with two switches on it. A sent signal on an end would not arrive to the other end unless the two buttons would allow it. The wire with the 2 buttons form an AND function without approximation.

FIGS. 6 to 9 demonstrate all cases of the described AND.

Let's have 2 pins linked with 2 distinct wires with a button each. A sent signal from a pin would not arrive to the other pin unless one of the buttons would allow it.

The 2 wires with the 2 buttons form an OR function without approximation.

FIGS. 10 to 13 demonstrate all cases of the described OR.

Let's have 2 parallel wires intersecting with another 2 parallel wires. A signal is sent in one of the first 2 and a signal is sent on one of the second 2. A special switch would connect 2 parallel wires and disconnect 2 parallel wires. Having the special switch connect a side would have a signal return on the other side.

The 4 wires with the special switch form a function ‘NOT’ without approximation. Putting the approximation free {AND′, ‘OR’, ‘NOT’} Functions together the way they are presented in FIGS. 1 to 4 would have us an approximation free universal gate as presented in FIGS. 14 to 16. A simplification of FIGS. 14 to 16 the way of FIGS. 17 and 18 would have us FIGS. 19 to 23. Where pins are put in connected groups. Changing a pin value would change all pins values in the group.

### Advantageous Effects of Invention

A signal could be some characteristics of a light like color, frequency or temperature, of an electric current or voltage, of a gas like sound or pressure, of a solid like sand, smoke or smell and finally of a liquid like taste or fluidity. It does not require semi-conductors or any kind of inner circuit switching (it does not require transistors) to realize some combinatorial logic and therefor the materialization of logic and programs could extend its domain out of electricity.

in the case of replacing the special switches with transistors like switches, the transistor like switches would be aligned having the same state.

### BRIEF DESCRIPTION OF DRAWINGS

FIG. 1 to FIG. 4 Demonstration of all the cases of an approximation-less Universal gate using an ‘OR’ and an ‘AND’

FIG. 5 A ‘NOT’ with wires only

FIG. 6 to FIG. 9 Demonstration of all the cases of an approximation-less ‘AND’

FIG. 10 to FIG. 13 Demonstration of all the cases of an approximation-less ‘OR’

FIG. 14 to 16 are the same than [FIG. 19 to 23]

FIG. 17 Approximation-less, universal gate construction demonstration.

FIG. 18 Used Symbols descriptions

FIG. 19 to 23 are frames of a movie demonstrating the propagation of signals when both switches are up.

FIG. 24 to 28 are frames of a movie demonstrating the propagation of signals when the upper switch is down and the bottom switch is up.

FIG. 29 to 33 are frames of a movie demonstrating the propagation of signals when the upper switch is up and the bottom switch is down.

FIG. 34 to 40 are frames of a movie demonstrating the propagation of signals when both switches are down.

FIG. 41 An example of a memory circuit using some kind of commanded switches like transistors or relays.

FIG. 43 to 46 Use of the technology to make a small adder by applying the adding logic formulas in FIG. 42.

FIG. 47 How to make a NAND with XORS

FIG. 48 An approximation of an OR with wires

FIG. 49 An approximation of an AND with wires

FIG. 50 to FIG. 53 Demonstration of all the cases of an approximation of a Universal gate using wires only

FIG. 54 to FIG. 57 An electric approximation of an AND with wires

FIG. 58 to FIG. 61 An electric approximation of an OR with wires

FIG. 62 A light transistor like switch.

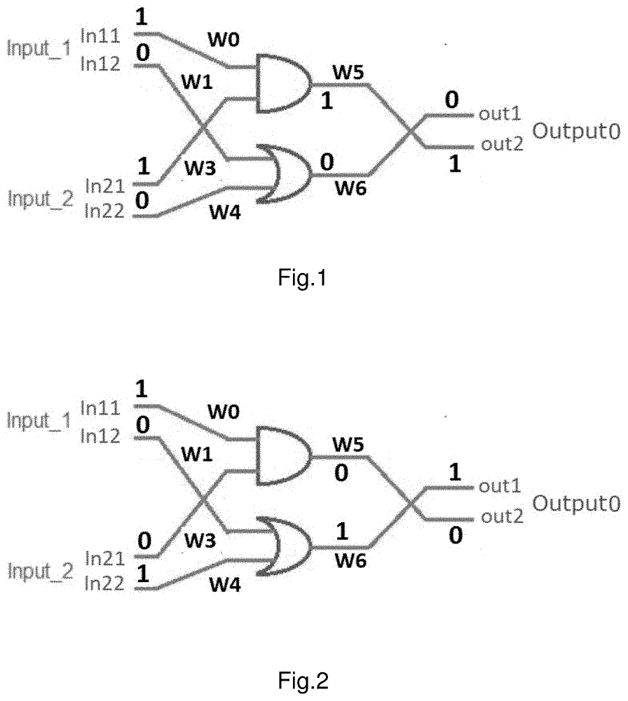

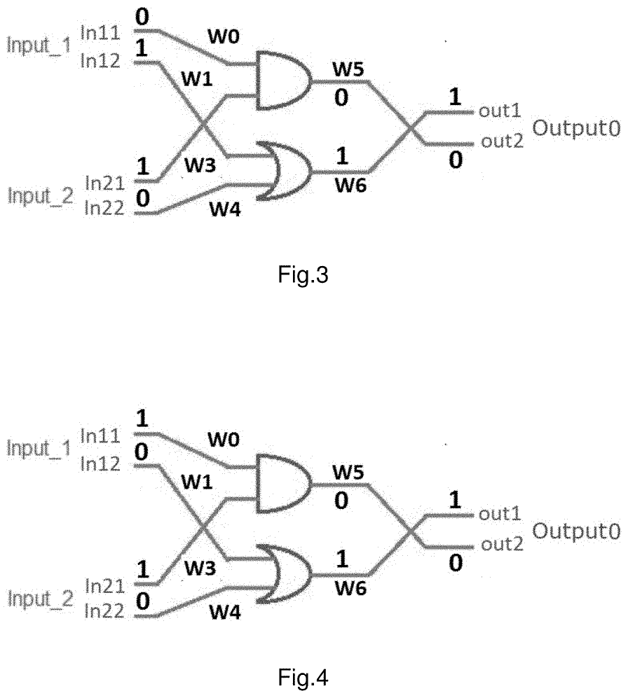

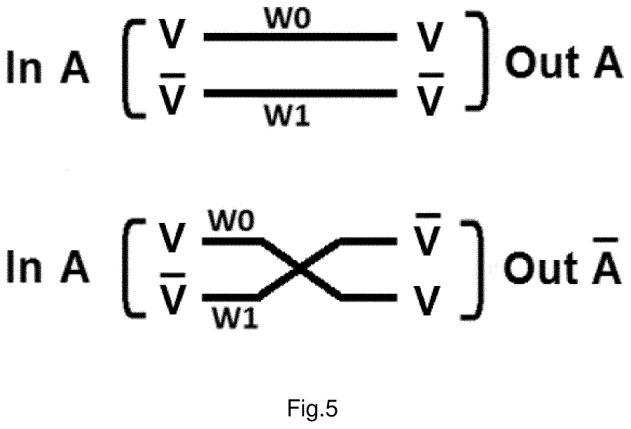

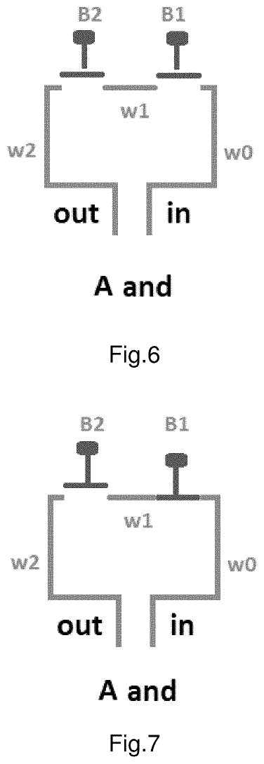

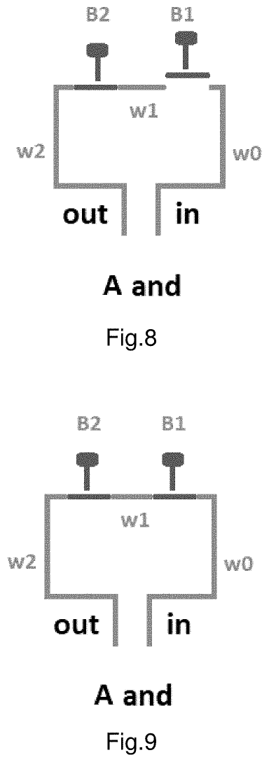

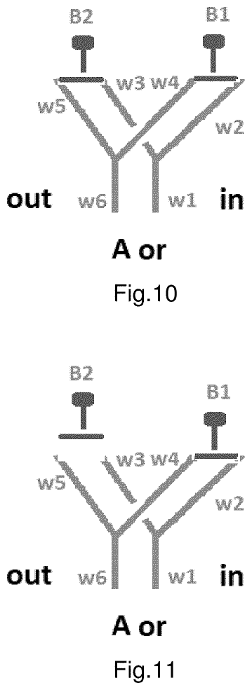

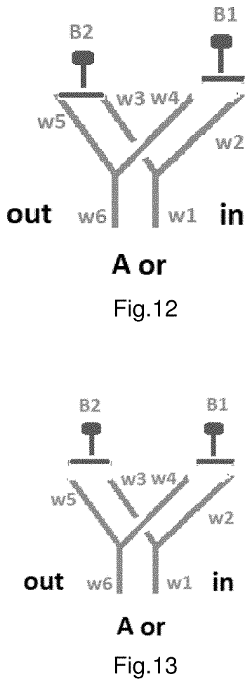

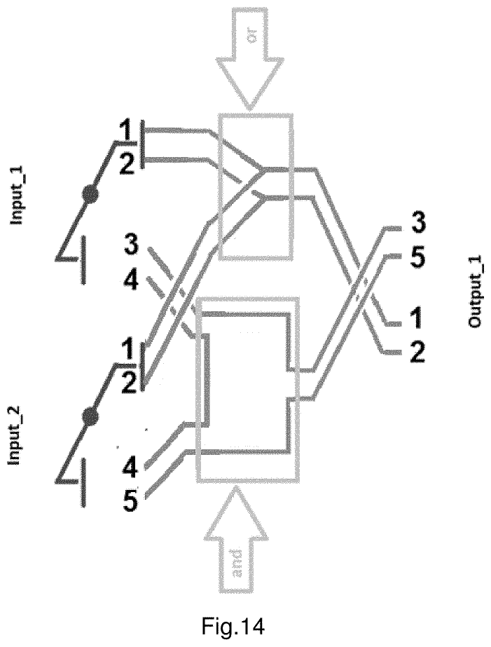

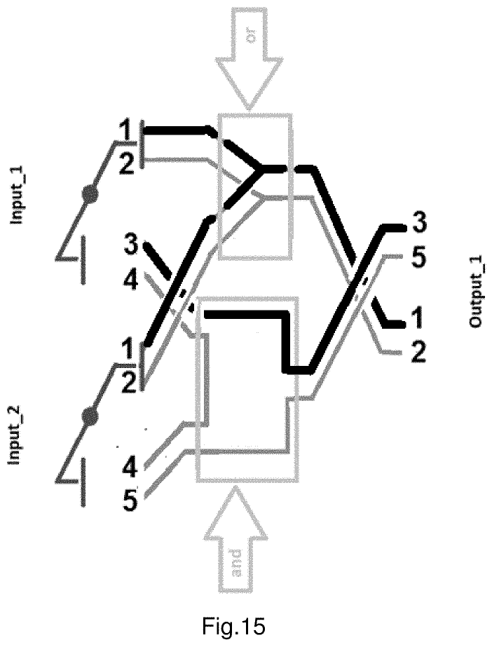

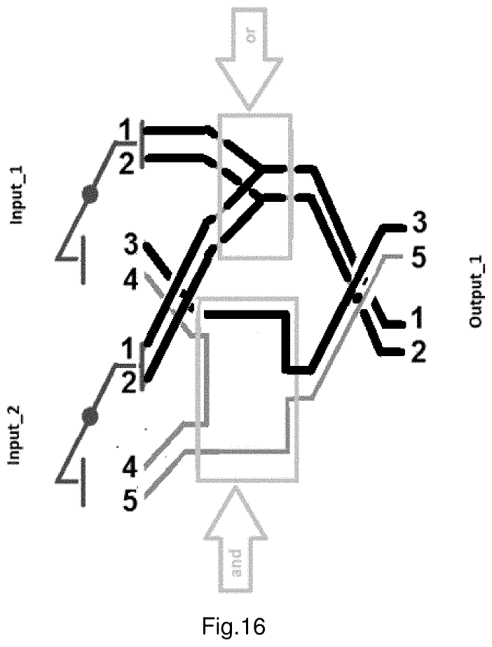

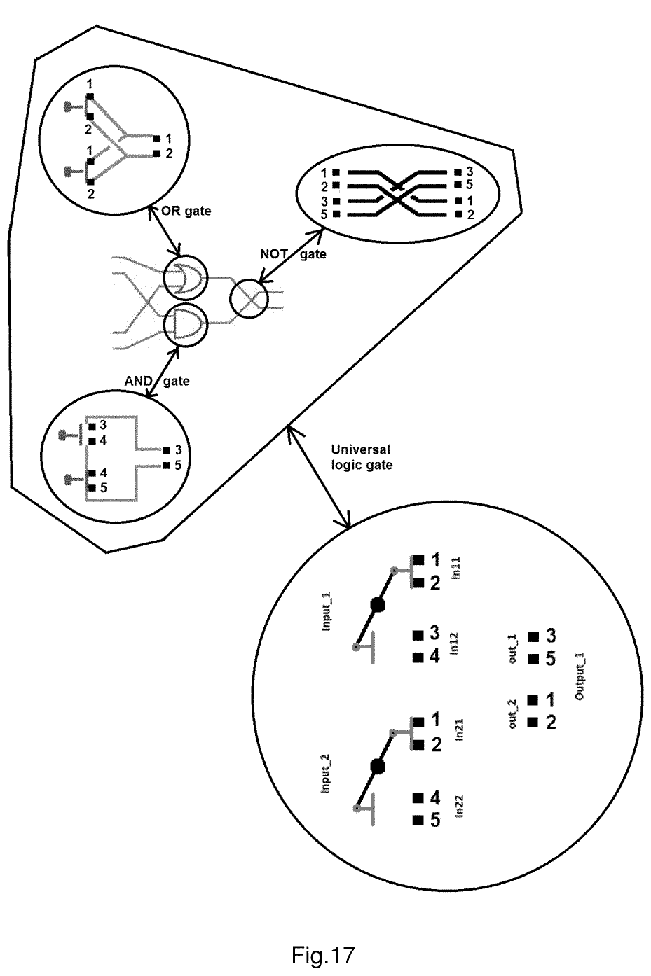

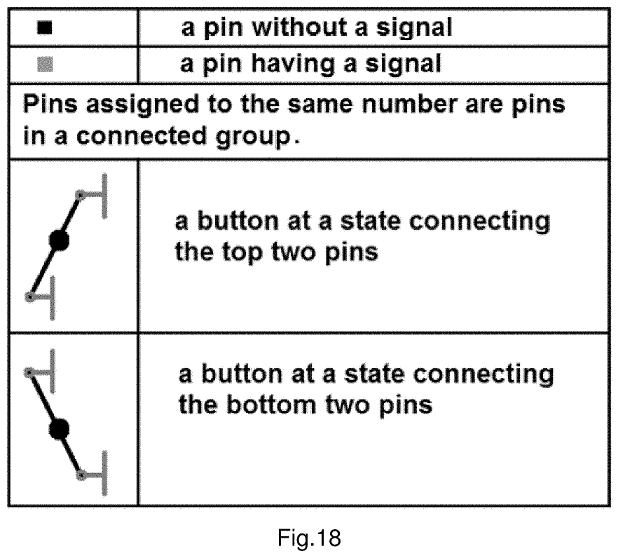

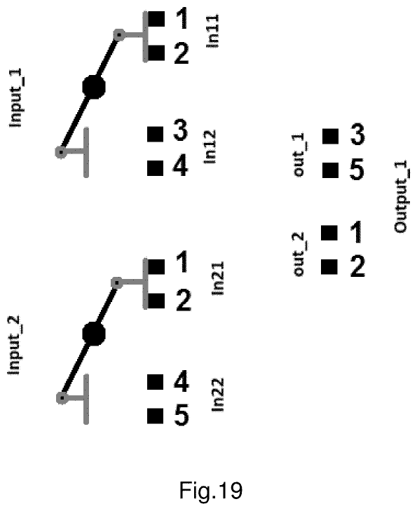

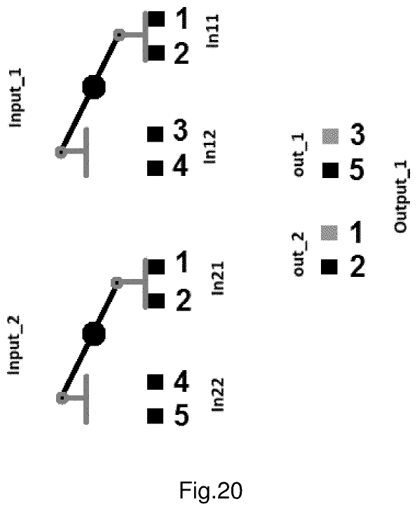

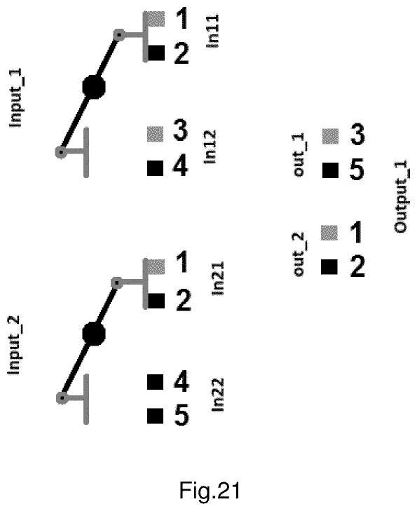

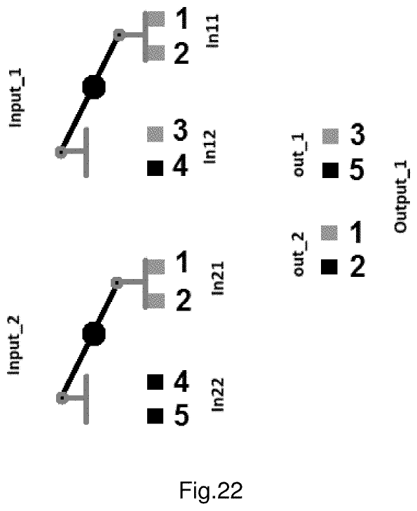

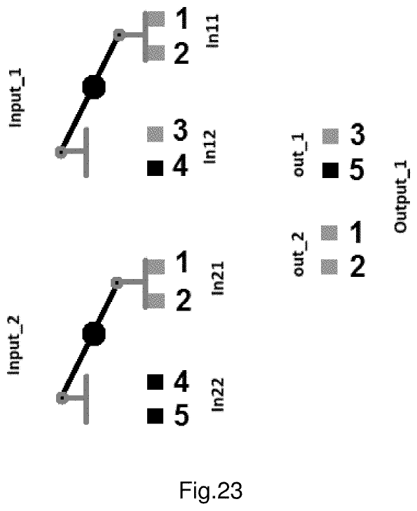

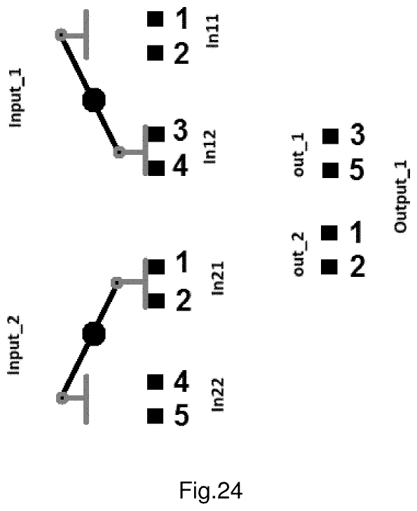

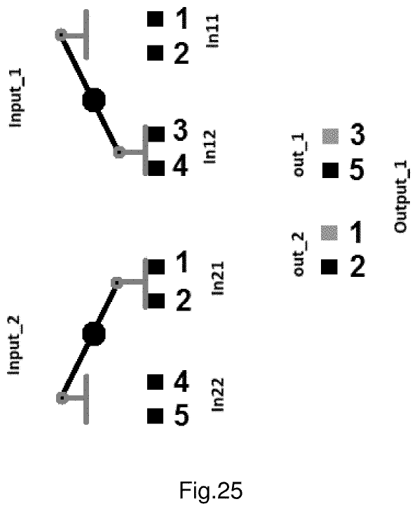

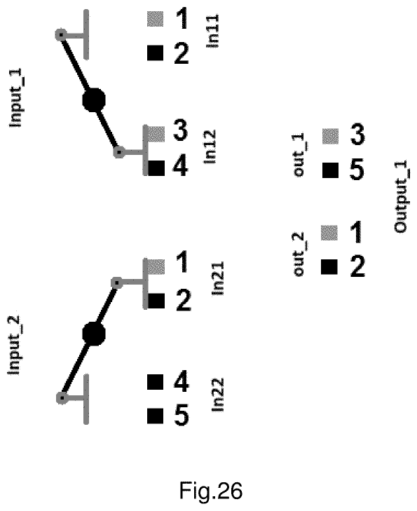

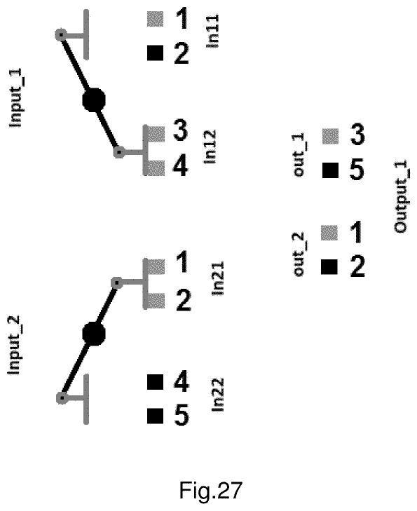

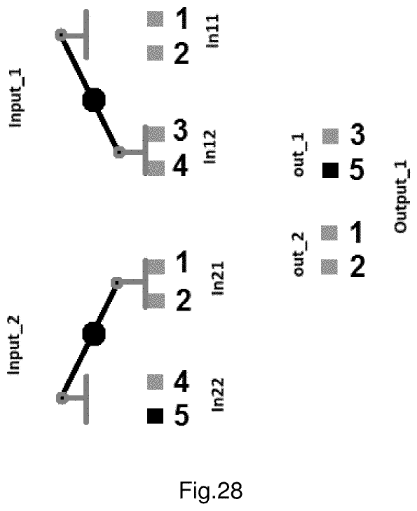

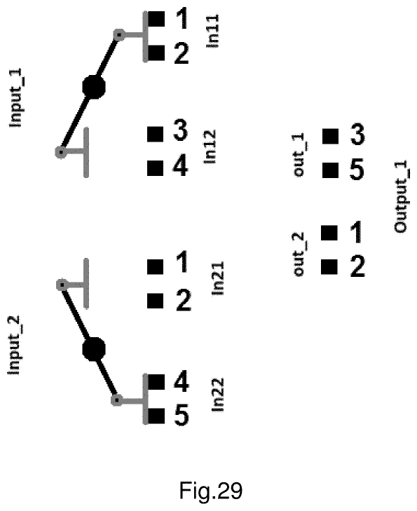

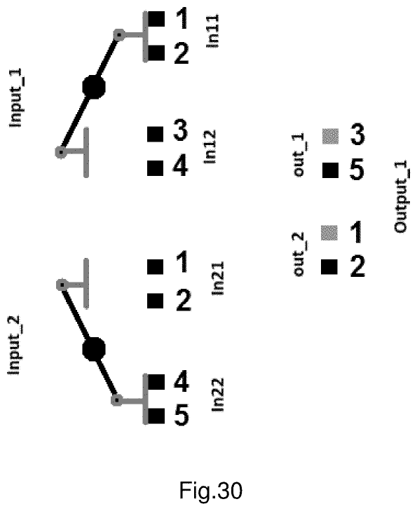

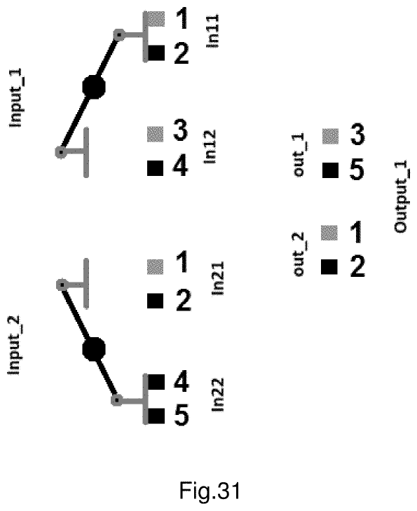

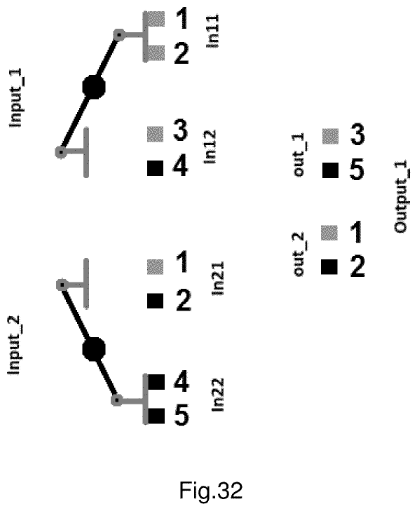

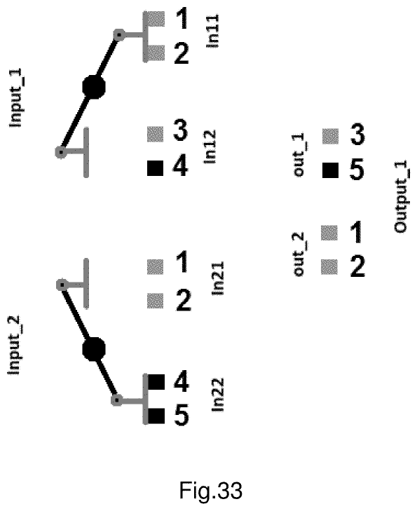

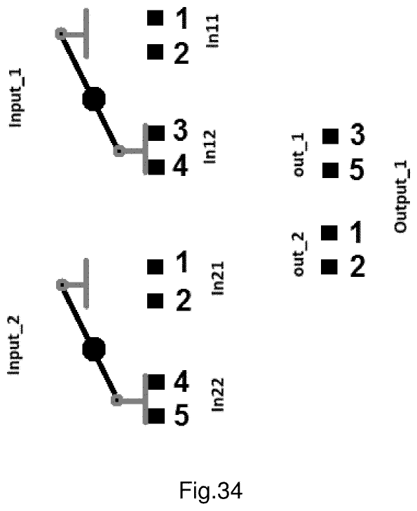

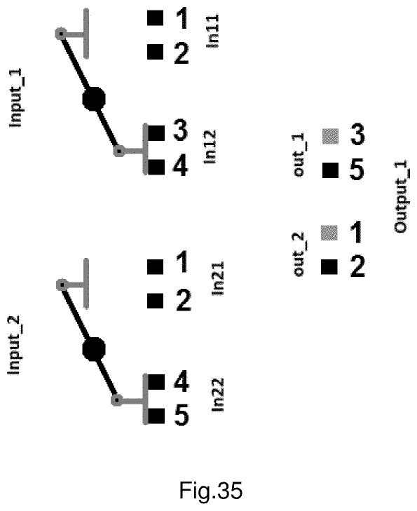

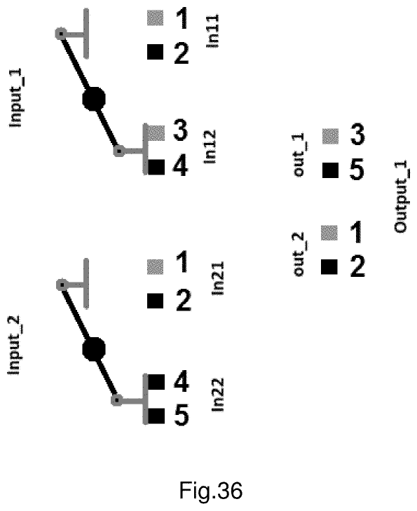

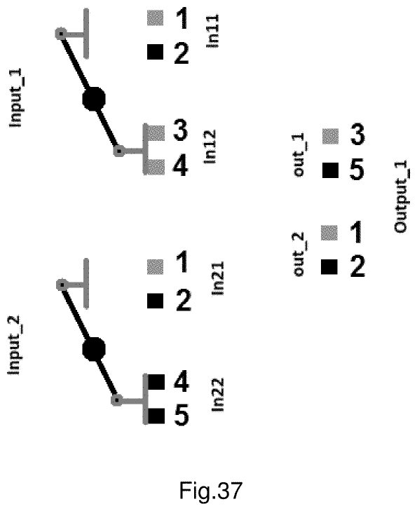

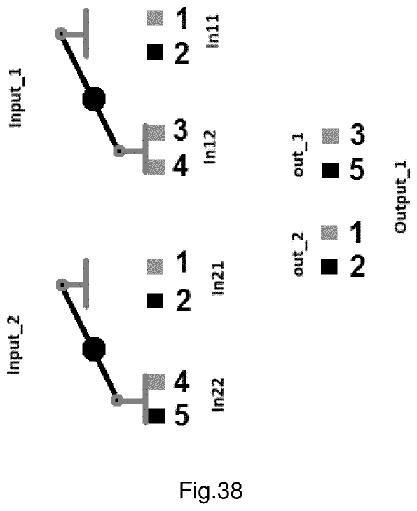

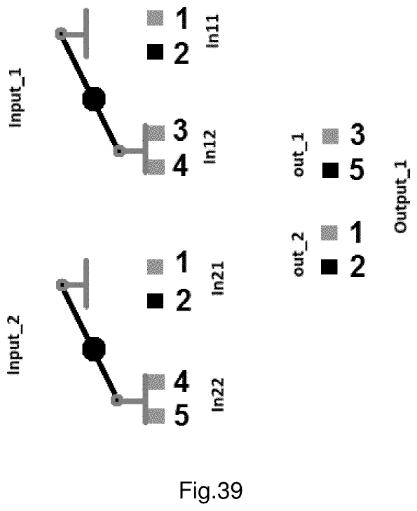

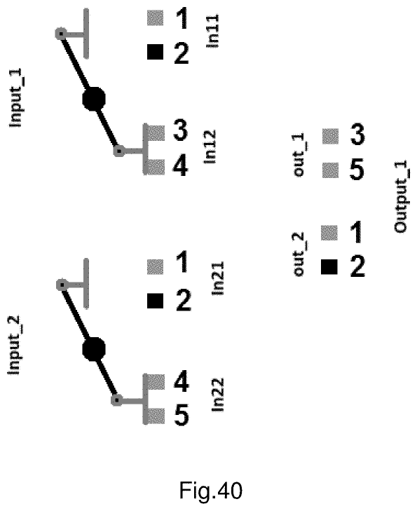

### DESCRIPTION OF EMBODIMENTS

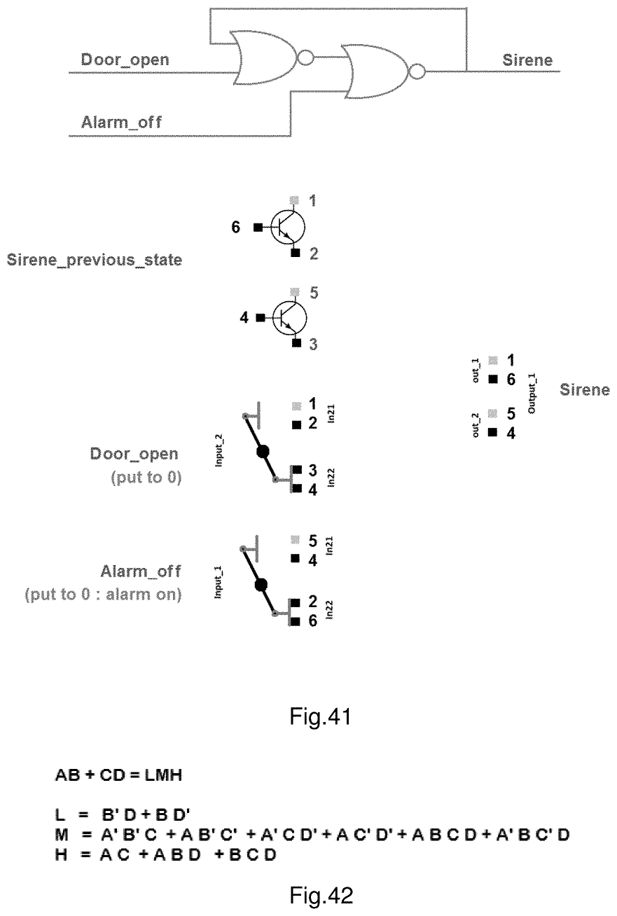

By combinatorial logic gates circuit, we mean a circuit with distinct inputs and outputs (no outputs are forwarded back to the inputs). A combinational logic circuit structure is included in a circuit that forwards back the outputs to the inputs. A circuit usually forwards back the outputs to the inputs for memory purposes. See FIG. 41. The apparatus described as a combinational logic circuit structure is made with switches and pins. A switch (or special switch) has 4 pins and two possible positions, connecting two of them at a position and the other two at the other position.

A transistor like switch can be by having a signal use to cut or allow the flow of a similar signal.

The input switches required for the embodiment of this apparatus can be by having 2 transistors if the signal is electric.

It is possible to have memory by having the outputs back to the inputs if the required switches are made with transistor like switches.

(Terminology: input switches, switches and special switches are equivalent terms.

Transistors, buttons and transistor like switches are also equivalent terms.

a switch is made of 2 transistor like switches.)

There are pins at the inputs with switches and pins at the outputs, if we remove the switches we can notice that pins are connected forming groups, where a value change to one pin in a group, is a value change to all pins in the group.

The embodiment of the described apparatus does not require a specific size like nanometers or kilometers or a specific material other than a material that can keep a group of pins connected given the chosen signal whether that is some characteristics of a light like color, frequency or temperature, of an electric current or voltage, of a gas like sound or pressure, of a solid like sand, smoke or smell and finally of a liquid like taste or fluidity.

many switches are possible like simple buttons, electro vans, electric transistors, vacuum tubes, relays, contactors, photonic transistors based on ring resonators, photonic transistors based on temperature effect on the refraction index or photonic transistors based on bistable switching in a photonic crystal.

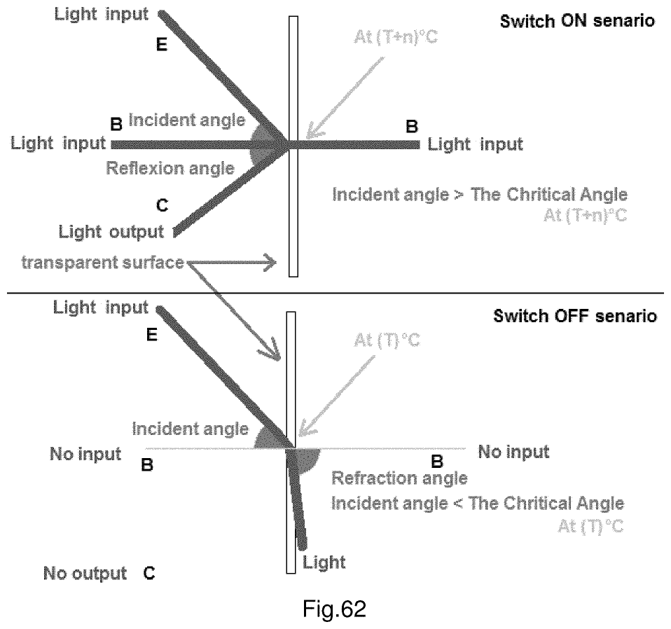

Other than the mechanical buttons like switches that are demonstrated in many figures there is a light transistor like switch demonstrated at FIG. 62.

If we pick Silicon as a transparent material as an example for FIG. 62, in a way to respect the current industry capabilities and a light of 1.1 microns wavelength operating at 21.85 and 19.85 degrees C. we would have respectively 3.54394 and 3.54352 refraction indices.

A critical angle is the biggest possible angle before having refraction become reflection.

refractionIndexOfAir*sin(refractedAngle)=refractionIndexOfSilicon*sin(incidentAngle)

refractionIndexOfAir*sin(90)=refractionIndexOfSilicon*sin(chriticalAngle)

The refraction index of air is −1.

When the heat increased the chriticalAngle (tolerence) went down.

21.85 and 19.85 degrees C. of Silicon would have respective critical angles of 16.3898 and 16.3918

So if the incidentAngle is 16.39 degrees the refraction regime would terminate to leave place to the total internal reflection regime and the reflectedAngle would be equal to the incidentAngle.

The heat would increase as the base would have a light pointing at one of the or at both sides of the transparent material.

### EXAMPLES

FIG. 41 An example of a memory circuit using some kind of commanded switches like transistors or relays to make an alarm system that would not shut the siren if the siren is ON and the door is re-closed.

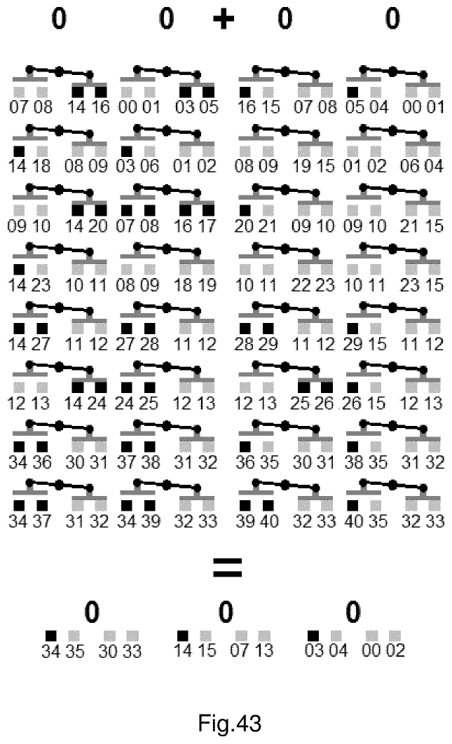

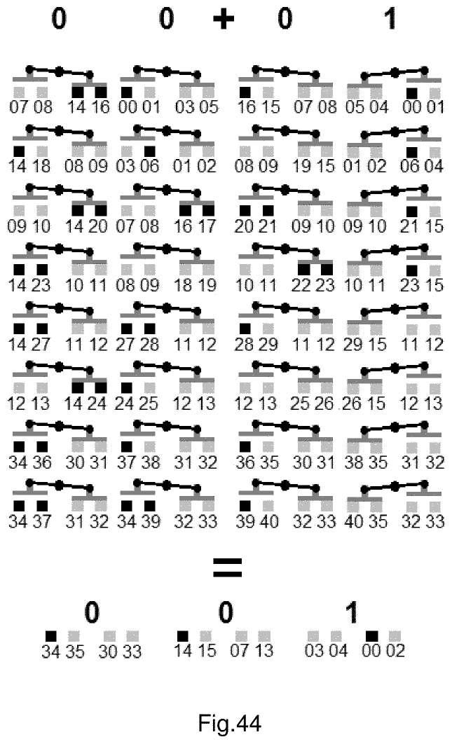

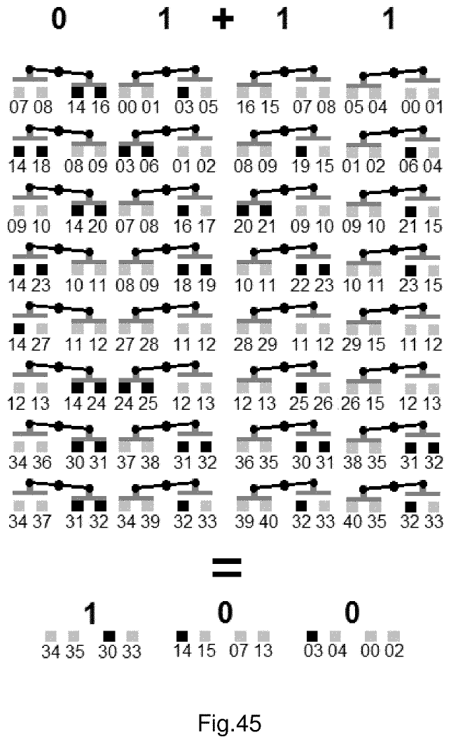

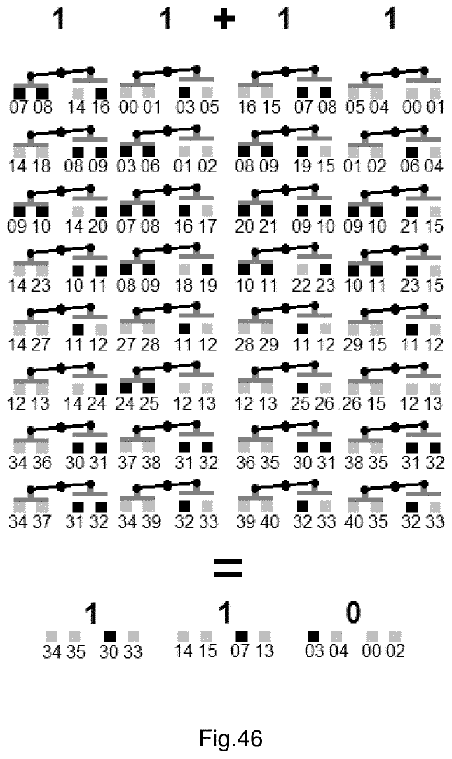

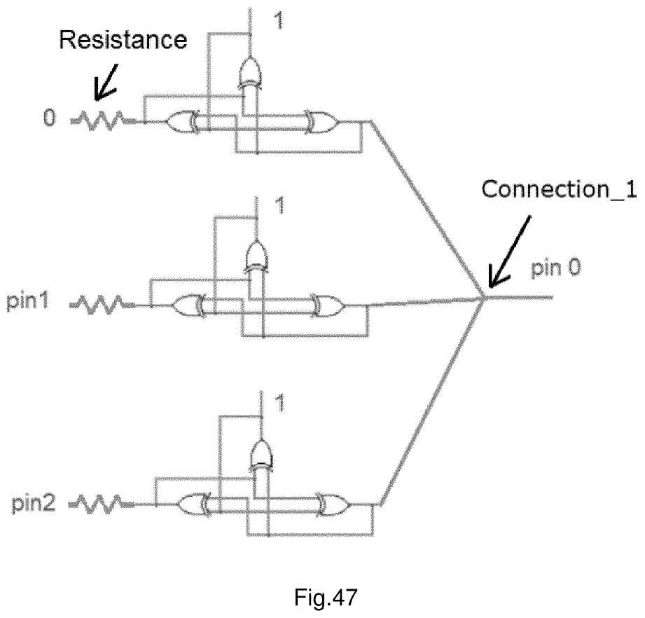

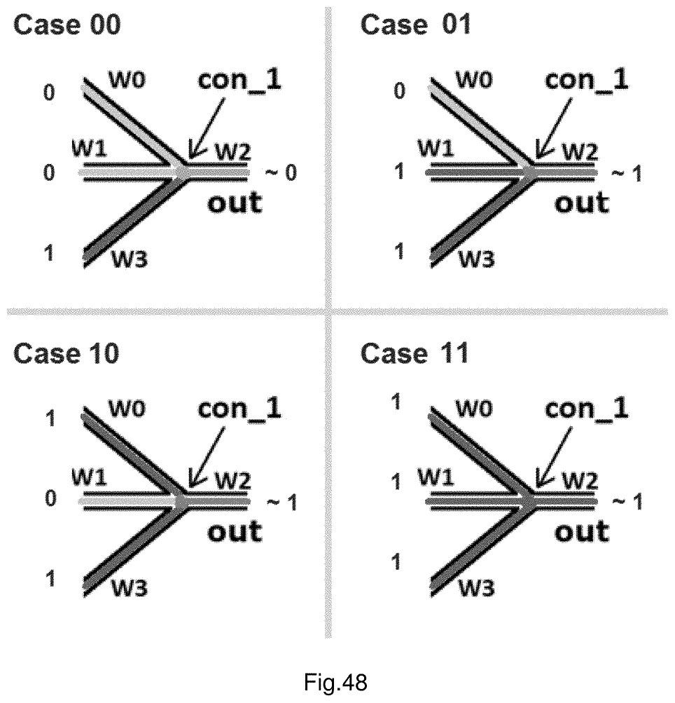

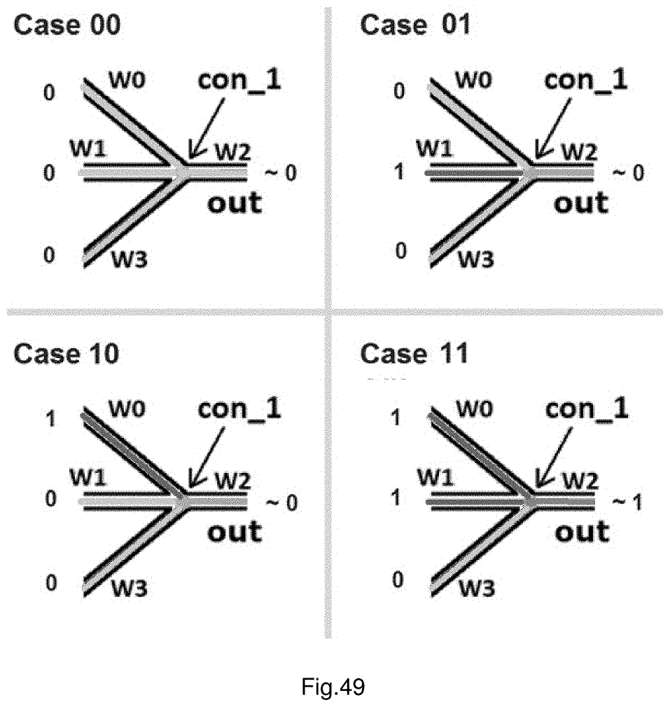

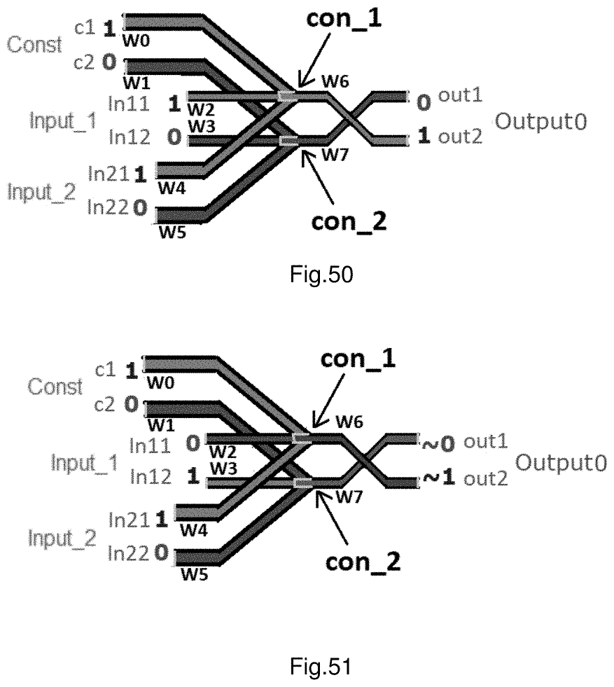

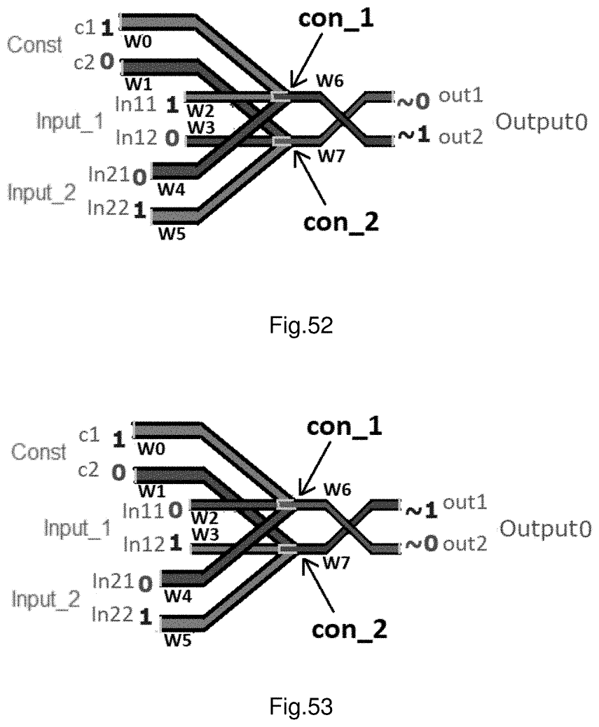

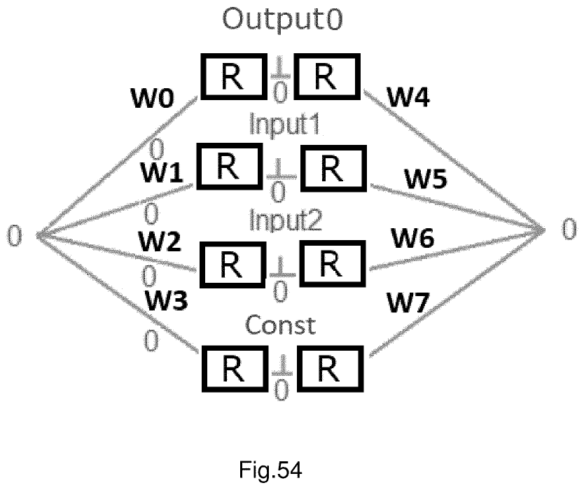

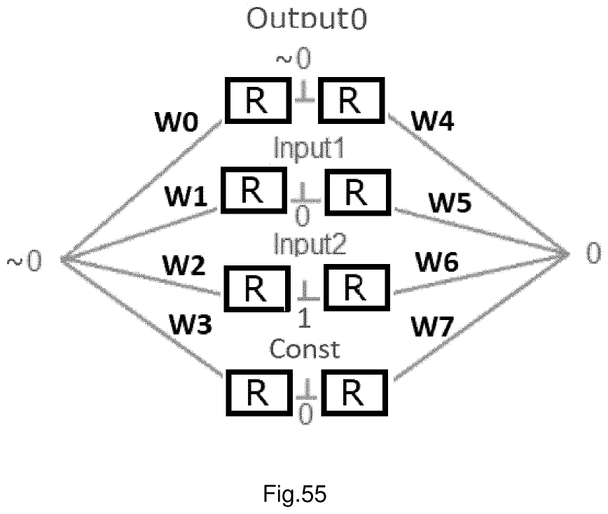

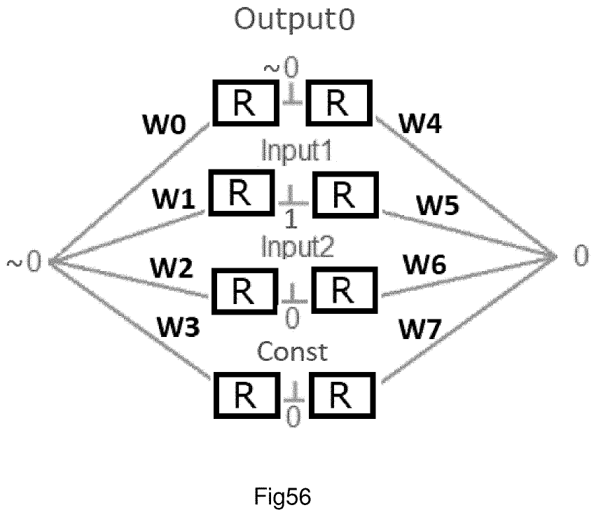

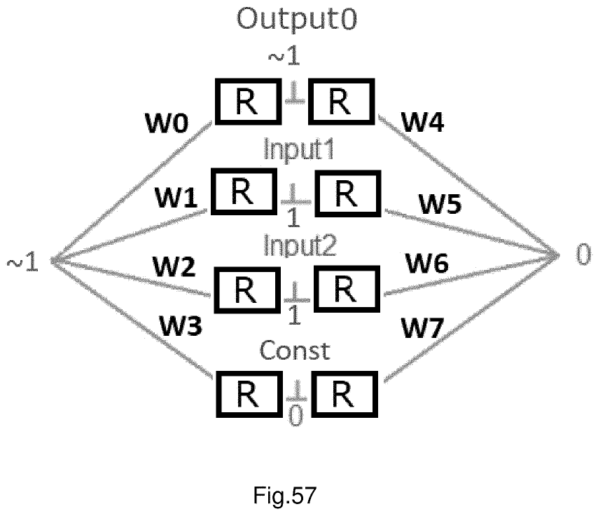

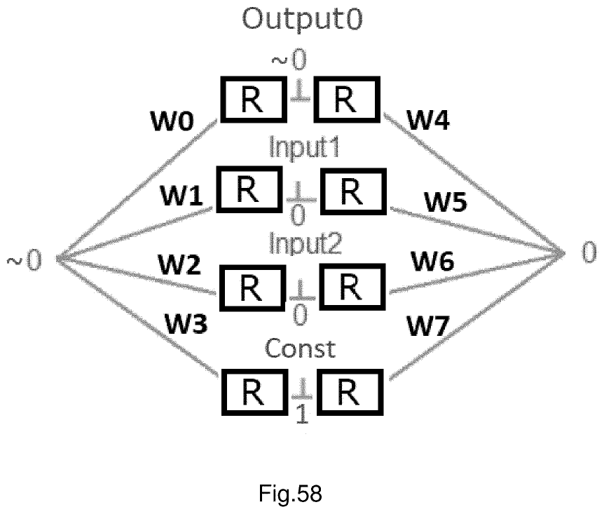

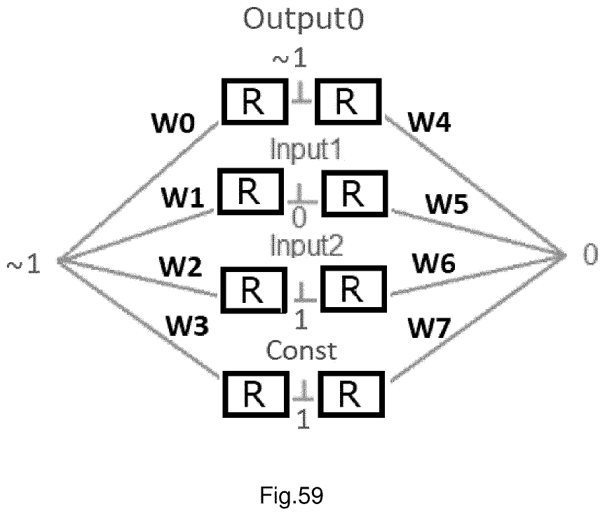

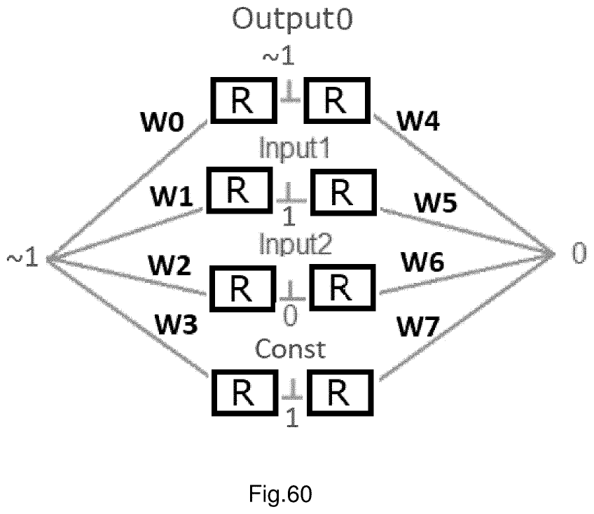

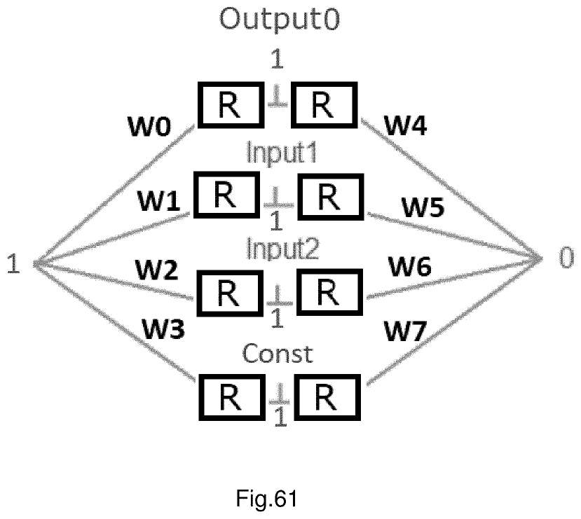

FIG. 43 to FIG. 46 Use of the technology to make a small adder with some examples like 11+11=110.

### INDUSTRIAL APPLICABILITY

It is highly relevant to chips manufacturers.

### CITATION LIST

A continuation in part of Ser. No. 16/024,909

Please notice the date of the first figure of the page 6/7 of the unpublished application Ser. No. 14/479,395

### Non-Patent Literature

NPL1: Temperature-dependent refractive index of silicon and germanium Bradley J. Frey, Douglas B. Leviton, Timothy J. Madison NASA Goddard Space Flight Center, Greenbelt, Md. 20771.
NPL2: Cascaded Microresonator-Based Matrix Switch for Silicon On-Chip Optical Interconnection By Andrew W. Poon, Member IEEE, Xianshu Luo, Student Member IEEE, Fang Xu, and Hui Che.
NPL3: All-optical transistor action with bistable switching in a photonic crystal cross-waveguide geometry Mehmet Fatih Yanik and Shanhui Fan Ginzton Laboratory, Stanford University, Stanford, Calif. 94304 Marin Soljačić and J. D. Joannopoulos Department of Physics, Massachusetts Institute of Technology, Cambridge, Mass. 02139.

1- A combinational logic circuit structure consisting of:
one or more inputs which are one or more pins, one or more outputs which are one or more pins, wherein the pins are subdivided into groups, wherein a value of a binary digit or of a void is determined by characteristics, of a light, of an electric signal, of a gas or of a liquid or of a solid and assigned to a pin, wherein a value change to one pin in a group is a value change to all pins in the group, wherein groups are connected to each other with input switches, and wherein groups are disconnected from each other with the said input switches.

2- A combinational logic circuit structure process consisting of the steps of:
Providing connected groups of one or more pins;
Providing a value of a binary digit or of a void determined by characteristics of a light, of an electric signal, of a gas or of a liquid or of a solid and assigned to a pin;
Providing some groups put at binary value and some groups put at void;
Providing switches configured to connect and disconnect some groups;
Wherein said switches decide the value of some groups.
